(19) United States
(12) Patent Application Publication
(10) Pub. No.: US 2019/0131472 A1
(43) Pub. Date: May 2, 2019

(54) SOLAR CELL

(71) Applicant: Industrial Technology Research Institute, Hsinchu (TW)

(72) Inventors: Jui-Chung Hsiao, New Taipei City (TW); Chun-Ming Yeh, Taipei City (TW); Chao-Cheng Lin, Taichung City (TW); Chorng-Jye Huang, Hsinchu City (TW); Chen-Hsun Du, Taipei City (TW); Chun-Heng Chen, Taipei City (TW)

(73) Assignee: Industrial Technology Research Institute, Hsinchu (TW)

(21) Appl. No.: 15/836,910

(22) Filed: Dec. 11, 2017

(30) Foreign Application Priority Data
Oct. 27, 2017 (TW) 106137211

(51) Int. Cl. H01L 31/0352; H01L 31/028; H01L 31/074; H01L 31/0368; H01L 31/0224

(52) U.S. Cl. CPC H01L 31/0352; H01L 31/028; H01L 31/022425; H01L 31/03682; H01L 31/074

(57) ABSTRACT

A solar cell includes a silicon substrate, a passivation structure, and a metal electrode. The passivation structure is disposed on a surface of the silicon substrate, and the passivation structure includes a tunneling layer and a doped polysilicon layer. The tunneling layer is disposed on the surface of the silicon substrate. The doped polysilicon layer is disposed on the tunneling layer and includes a first region and a second region having different thicknesses from each other, and the thickness of the first region is greater than that of the second region, wherein the thickness of the first region is between 50 nm and 500 nm, and the thickness of the second region is greater than 0 and equal to or less than 250 nm. The metal electrode is disposed on the first region of the doped polysilicon layer.

### CROSS-REFERENCE TO RELATED APPLICATION

This application claims the priority benefits of Taiwan application serial no. 106137211, filed on Oct. 27, 2017. The disclosure of which is hereby incorporated by reference herein in its entirety.

### TECHNICAL FIELD

The technical field relates to a solar cell.

### BACKGROUND

Tunneling solar cells are currently under development, such as heterojunction silicon solar cells, and they are a kind of high efficiency solar cells. They have considerably enhanced electricity generation capacity and thereby reduce the cost of power generation.

In terms of common tunneling solar cells, during the manufacturing process, a silicon oxide layer is usually grown on one side of a silicon wafer to serve as a tunneling layer. However, since this silicon oxide layer cannot have good surface passivation characteristics, a high-temperature annealing process is required for improving passivation quality.

The aforesaid high-temperature annealing process is usually performed in a furnace. However, under high temperature conditions, the silicon oxide layer grows such that carriers within the silicon wafer cannot be freely transported via the tunneling mechanism. Accordingly, before performing the annealing process, a doped amorphous silicon layer may be formed on the silicon oxide layer in order to prevent excessive growth of the silicon oxide layer. After the annealing process, the doped amorphous silicon layer is transformed into a doped polysilicon layer.

However, common polysilicon layers have an energy gap of 1.1 eV, and may thus affect optical absorption. As a result, light entering the silicon wafer may be somewhat lost.

### SUMMARY

One of exemplary embodiments of the disclosure provides a solar cell. The solar cell includes a silicon substrate having a first surface and a second surface, a first passivation structure disposed on the first surface of the silicon substrate, and a first metal electrode disposed on the first passivation structure. The first passivation structure includes a tunneling layer and a doped polysilicon layer. The tunneling layer is disposed on the first surface of the silicon substrate, and the doped polysilicon layer is disposed on the tunneling layer. The doped polysilicon layer includes a first region and a second region having different thicknesses from each other, and the thickness of the first region is greater than the thickness of the second region, wherein the thickness of the first region is between 50 nm and 500 nm, and the thickness of the second region is greater than 0 and equal to or less than 250 nm. The first metal electrode is disposed on the first region of the doped polysilicon layer.

Several exemplary embodiments accompanied with figures are described in detail below to further describe the disclosure in details.

### BRIEF DESCRIPTION OF THE DRAWINGS

FIG. 1 is a schematic view of a solar cell according to a first embodiment of the disclosure.

FIG. 2A illustrates a modification of the first embodiment.

FIG. 2B illustrates another modification of the first embodiment.

FIG. 3 is a schematic view of a solar cell according to a second embodiment of the disclosure.

FIG. 4A is a curve diagram showing a relationship between second region thickness and short-circuit current (J_{SC}) in Simulation Experiment 1.

FIG. 4B is a curve diagram showing a relationship between second region thickness and fill factor (FF) in Simulation Experiment 1.

FIG. 4C is a curve diagram showing a relationship between second region thickness and open-circuit voltage (Voc) in Simulation Experiment 1.

FIG. 4D is a curve diagram showing a relationship between second region thickness and battery conversion efficiency in Simulation Experiment 1.

FIG. 5 is a curve diagram showing battery conversion efficiency varying with a ratio of second region thickness to first region thickness in Simulation Experiment 2.

### DETAILED DESCRIPTION OF DISCLOSED EMBODIMENTS

Several exemplary embodiments accompanied with figures are described in detail below. However, the exemplary embodiments described herein are not intended to limit the scope of the disclosure. In addition, the figures only serve the purpose of illustration and are not illustrated according to actual dimensions, and different layers or regions may be enlarged or contracted so as to be shown in a single figure. Moreover, although terms such as “first” and “second” are used herein to indicate different elements, regions and/or layers, these elements, regions and/or layers are not to be limited by these terms. Rather, these terms are only used to distinguish one element, region, or layer, from another element, region, or layer. Thus, a first element, region, or layer mentioned below may also be referred to as a second element, region, or layer, without departing from the teachings of the exemplary embodiments. Moreover, to facilitate understanding, the same elements will hereinafter be denoted by the same reference numerals.

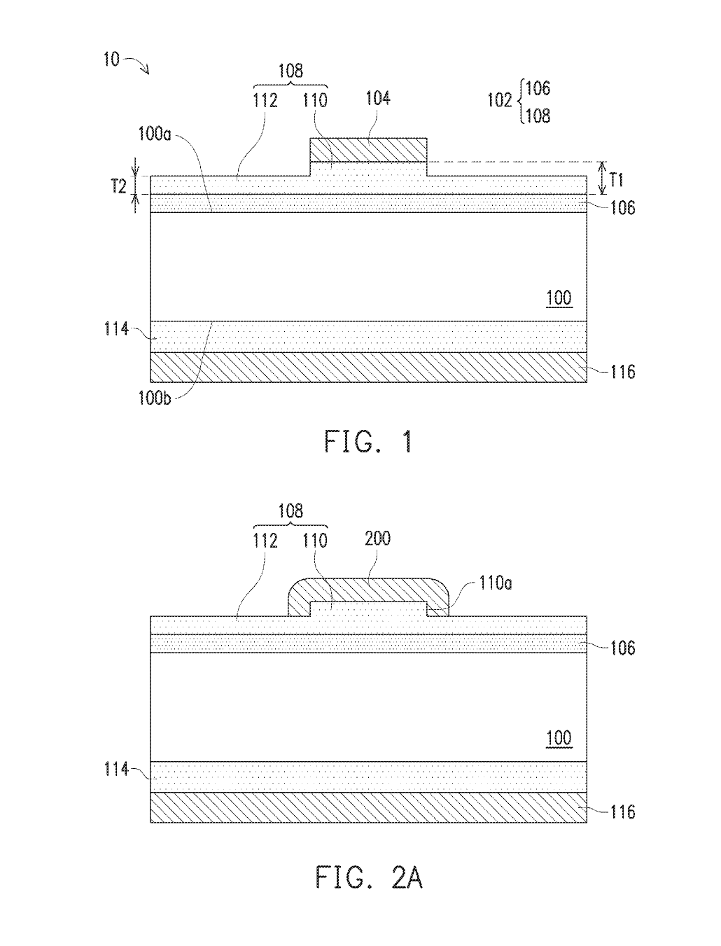

FIG. 1 is a schematic view of a solar cell according to a first embodiment of the disclosure.

Referring to FIG. 1, a solar cell 10 of the first embodiment basically includes a silicon substrate 100, a passivation structure 102 and a metal electrode 104, and the silicon substrate 100 has a first surface 100a and a second surface 100b. In the present embodiment, the first surface 100a is the front surface (i.e., sunlight enters from the first surface 100a), and the second surface 100b is the back surface. However, the disclosure is not limited thereto, and sunlight may also enter the solar cell from the second surface 100b. The passivation structure 102 of the first embodiment is disposed on the first surface 100a of the silicon substrate 100, and the passivation structure 102 includes a tunneling layer 106 and a doped polysilicon layer 108. The silicon substrate 100 serves as a light absorption layer in the solar cell 10, and is capable of, after absorbing the sunlight, generating electron-hole pairs to produce electrical energy. The tunneling layer 106 is disposed on the first surface 100a of the silicon substrate 100, and has a function of passivating surface defects of a wafer (i.e., the silicon substrate 100) to reduce carrier recombination, wherein the tunneling layer 106 includes, for example, silicon oxide (SiO₂), silicon oxynitride (SiON), aluminum oxide (Al₂O₃) or silicon nitride (SiN). The doped polysilicon layer 108 is disposed on the tunneling layer 106 and is configured to collect minority carriers, wherein the doped polysilicon layer 108 includes, for example, a polysilicon film, polycrystalline silicon oxide or polycrystalline silicon carbide. For example, if the silicon substrate 100 is an n-type silicon wafer, the doped polysilicon layer 108 may be p+ polysilicon.

In the present embodiment, the doped polysilicon layer 108 includes a first region 110 and a second region 112 having different thicknesses from each other, and a thickness T1 of the first region 110 is greater than a thickness T2 of the second region 112, wherein the thickness T1 of the first region 110 is between 50 nm and 500 nm, and the thickness T2 of the second region 112 is greater than 0 and equal to or less than 250 nm. Due to the thickness difference in the structure of the doped polysilicon layer 108, the incident light absorbed by the second region 112 of the doped polysilicon layer 108 can be reduced. In the meantime, minority carriers can be collected by the doped polysilicon layer 108, so as to improve short-circuit current and conversion efficiency. The doped polysilicon layer 108 of the present embodiment may be formed in the following manner. First, a doped amorphous silicon or polysilicon film having the thickness T2 is formed all over a surface of the tunneling layer 106 by a chemical vapor deposition (CVD) process. Next, the second region 112 is covered by a mask, while the doped amorphous silicon or polysilicon film is continuously deposited, thus forming the first region 110 having the thickness T1. Then, a thermal diffusion process is performed to complete fabrication of the doped polysilicon layer 108. The metal electrode 104 is disposed on the first region 110 of the doped polysilicon layer 108. The metal electrode 104 may be a metal electrode used in the solar cell field, such as aluminum (Al), silver (Ag), molybdenum (Mo), gold (Au), platinum (Pt), nickel (Ni) or copper (Cu). The aforesaid mask used in fabricating the doped polysilicon layer 108 may also be used during formation of the metal electrode 104.

In one exemplary embodiment, the thickness T1 of the first region 110 is between 50 nm and 300 nm, and the thickness T2 of the second region 112 is ½ time to 1/50 time the thickness T1 of the first region 110. In another exemplary embodiment, the thickness T2 of the second region 112 is between 1 nm and 150 nm. Moreover, in view of battery conversion efficiency, as the thickness T1 of the first region 110 decreases, a ratio (T2/T1) of the thickness T2 of the second region 112 to the thickness T1 of the first region 110 preferably decreases. For example, if the thickness T1 of the first region 110 is 200 nm or less, the thickness T2 of the second region 112 is preferably 40 nm or less (i.e., T2/T1=1/5 or less); if the thickness T1 of the first region 110 is 180 nm or less, the thickness T2 of the second region 112 is preferably 18 nm or less (i.e., T2/T1=1/10 or less).

In FIG. 1, a back surface field (BSF) layer 114 and a back side electrode 116 are further disposed on the second surface 100b of the silicon substrate 100, wherein the BSF layer 114 reduces the number of minority carriers on the second surface 100b of the silicon substrate 100 by a back surface field so as to reduce recombination. For example, if the silicon substrate 100 is an n-type silicon wafer, the BSF layer 114 may be an n+ diffusion layer. The back side electrode 116 may be a metal electrode used in the solar cell field, such as Al, Ag, Mo, Au, Pt, Ni or Cu.

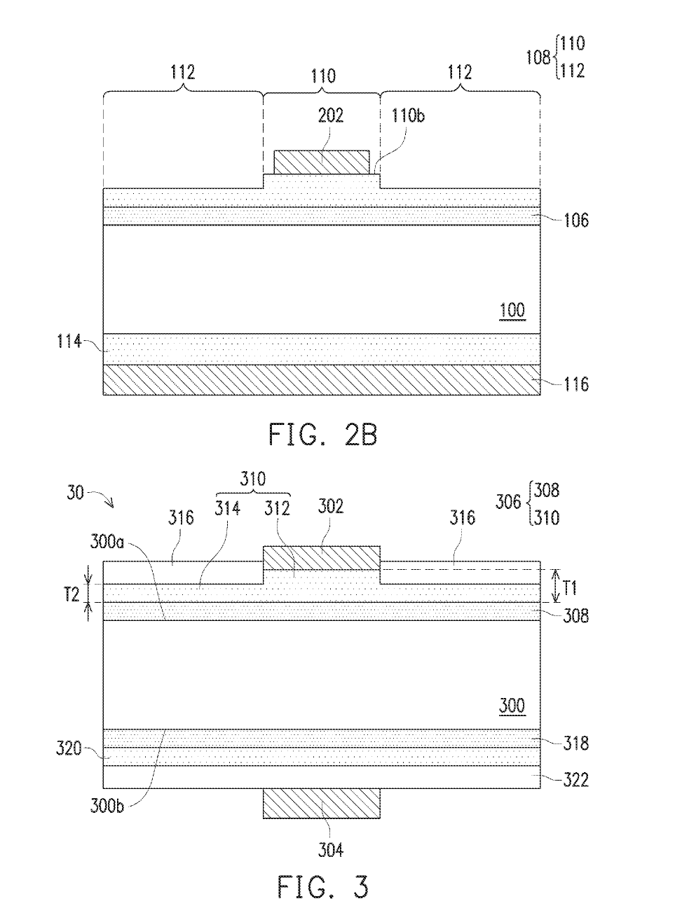

FIG. 2A illustrates a modification of the first embodiment, wherein the same reference numerals as those in FIG. 1 indicate the same or similar elements, and repeated description of the same technical content is omitted.

A difference between the structures of FIG. 2A and FIG. 1 is that, in FIG. 2A, a metal electrode 200 is disposed above the first region 110 of the doped polysilicon layer 108 and also covers a sidewall 110a of the first region 110. Thus, the metal electrode 200 contacts a portion of the second region 112. In other words, the area of the first region 110 is smaller than the area of the metal electrode 200.

FIG. 2B illustrates another modification of the first embodiment, wherein the same reference numerals as those in FIG. 1 indicate the same or similar elements, and repeated description of the same technical content is omitted.

A difference between the structures of FIG. 2B and FIG. 1 is that, in FIG. 2B, a metal electrode 202 is disposed above the first region 110 of the doped polysilicon layer 108 does not completely cover the first region 110, thus a portion of a top surface 110b of the first region 110 is exposed. In other words, the area of the first region 110 is greater than the area of the metal electrode 202.

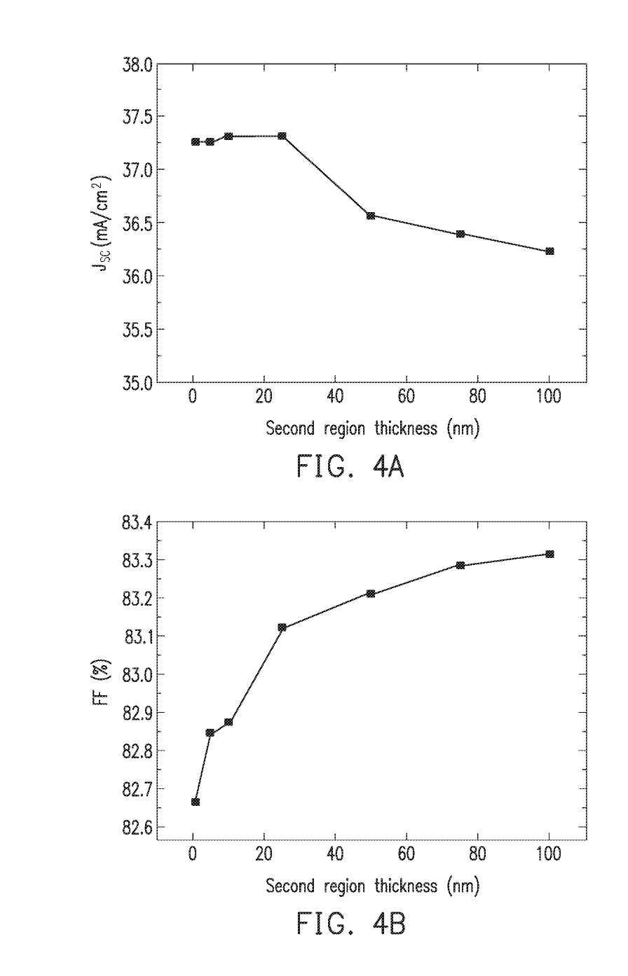

FIG. 3 is a schematic view of a solar cell according to a second embodiment of the disclosure.

Referring to FIG. 3, a solar cell 30 of the second embodiment is a bifacial solar cell including a silicon substrate 300, a first metal electrode 302, a second metal electrode 304 and a passivation structure 306. Sunlight may enter the solar cell 30 from a first surface 300a and a second surface 300b of the silicon substrate 300. The first metal electrode 302 is disposed on the first surface 300a of the silicon substrate 300, and the second metal electrode 304 is disposed on the second surface 300b of the silicon substrate 300. The passivation structure 306 is at least disposed between the first surface 300a and the first metal electrode 302 or between the second surface 300b and the second metal electrode 304. The present embodiment gives an example where the passivation structure 306 is disposed between the first surface 300a and the first metal electrode 302. However, the disclosure is not limited thereto. The passivation structure 306 includes a tunneling layer 308 and a doped polysilicon layer 310. The tunneling layer 308 is disposed on the first surface 300a of the silicon substrate 300, and has a function of passivating surface defects of a wafer (i.e., the silicon substrate 300) to reduce carrier recombination, wherein the tunneling layer 308 includes, for example, silicon oxide (SiO₂), silicon oxynitride (SiON), aluminum oxide (Al₂O₃) or silicon nitride (SiN). The doped polysilicon layer 310 is disposed between the tunneling layer 308 and the first metal electrode 302 and is configured to collect minority carriers, wherein the doped polysilicon layer 310 includes, for example, a polysilicon film, polycrystalline silicon oxide or polycrystalline silicon carbide.

In the present embodiment, the doped polysilicon layer 310 includes a first region 312 and a second region 314 having different thicknesses from each other. The first region 312 is interposed between the tunneling layer 308 and the first metal electrode 302, and the thickness T1 of the first region 312 is greater than the thickness T2 of the second region 314, wherein the thickness T1 of the first region 312 is between 50 nm and 500 nm, and the thickness T2 of the second region 314 is greater than 0 and equal to or less than 250 nm. Due to the thickness difference in the structure of the doped polysilicon layer 310, the incident light absorbed by polysilicon can be reduced. In the meantime, minority carriers can be collected by the doped polysilicon layer 310, so as to improve short-circuit current and conversion efficiency. In the present embodiment, the area of the first region 312 is equal to the area of the first metal electrode 302. However, the disclosure is not limited thereto, and the area of the first region 312 may also be greater than or smaller than the area of the first metal electrode 302.

In one exemplary embodiment, the thickness T1 of the first region 312 is between 50 nm and 300 nm, and the thickness T2 of the second region 314 is ½ time to 1/50 time the thickness T1 of the first region 312. In another exemplary embodiment, the thickness T2 of the second region 314 is between 1 nm and 150 nm. Moreover, in view of battery conversion efficiency, as the thickness T1 of the first region 312 decreases, the ratio (T2/T1) of the thickness T2 of the second region 314 to the thickness T1 of the first region 312 preferably decreases. For example, if the thickness T1 of the first region 312 is 200 nm or less, the thickness T2 of the second region 314 is preferably 40 nm or less (i.e., T2/T1=1/5 or less); if the thickness T1 of the first region 312 is 180 nm or less, the thickness T2 of the second region 314 is preferably 18 nm or less (i.e., T2/T1=1/10 or less).

In FIG. 3, the first metal electrode 302 and the second metal electrode 304 may be metal electrodes used in the solar cell field, such as Al, Ag, Mo, Au, Pt, Ni or Cu, and the first metal electrode 302 and the second metal electrode 304 may be made of the same or different materials. In addition, an anti-reflection layer 316 may further be disposed on the second region 314 of the doped polysilicon layer 310 disposed on the first surface 300a of the silicon substrate 300, so as to reduce reflection of incident light, wherein the anti-reflection layer 316 may be made of silicon nitride (SiNx), SiON, aluminum oxide (Al₂O₃), silicon carbide (SiC), tungsten oxide (WOx), titanium dioxide (TiO₂), tantalum pentoxide (Ta₂O₅) or other suitable material. Alternatively, the antireflection layer 316 herein may be a transparent conducting oxide (TCO) material to achieve the same anti-reflection effect.

In addition, a passivation structure composed of another tunneling layer 318 and another doped polysilicon layer 320 is further disposed on the second surface 300b of the silicon substrate 300, wherein, similarly as the tunneling layer 308, the tunneling layer 318 has the function of passivating surface defects of a wafer (i.e., the silicon substrate 300) to reduce carrier recombination. The tunneling layer 318 is made of, for example, SiO₂, SiON, Al₂O₃, or SiN. The doped polysilicon layer 320 may be a layer having uniform thickness disposed between the tunneling layer 318 and the second metal electrode 304, and is configured to collect minority carriers. In view of electrical transmission, a transparent conducting oxide (TCO) layer 322 may further be disposed all over between the doped polysilicon layer 320 and the second metal electrode 304. The TCO layer is made of, for example, indium tin oxide (ITO), indium zinc oxide (IZO), aluminum tin oxide (ATO), gallium-doped zinc oxide (GZO), aluminum gallium zinc oxide (AGZO), cadmium tin oxide (CTO), zinc oxide (ZnO), zirconium dioxide (ZrO₂) or other suitable material. In another exemplary embodiment, similarly as the doped polysilicon layer 310, the doped polysilicon layer 320 may include a first region and a second region having different thicknesses from each other. The second metal electrode 304 may be disposed on the first region of the doped polysilicon layer 320 in this passivation structure, and the thickness difference between the first region and the second region is omitted from description since it can be understood from the above description.

In the following, the effects of the exemplary embodiments of the disclosure are verified by way of simulation. However, the scope of the disclosure is not limited to the following descriptions.

Simulation Experiment 1

A solar cell of Simulation Experiment 1 is as shown in FIG. 1. The simulating solar cell structure includes an n-type silicon substrate, an n+ diffusion layer serving as a BSF, upper and lower electrodes, a tunneling layer (having a thickness of 1 nm), and a doped polysilicon layer, wherein the doped polysilicon layer was divided into two regions, namely a first region below the upper electrode, and a second region outside the upper electrode. The thickness of the first region is fixed at 100 nm, and the thickness of the second region is a variable. The effects of the solar cell are analyzed.

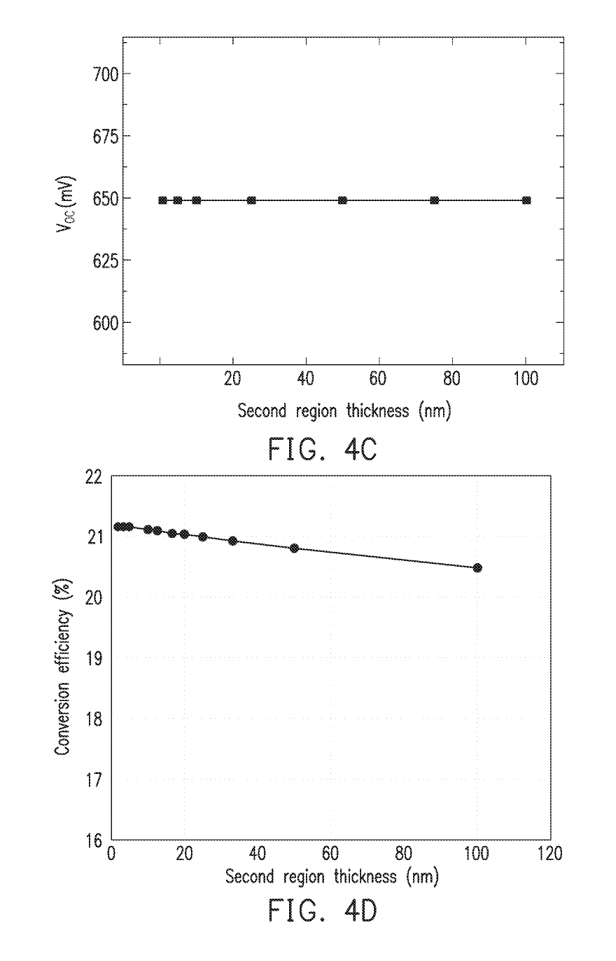

FIG. 4A to FIG. 4D respectively show characteristic numerical values of a solar cell which are calculated using the aforesaid solar cell structure of Simulation Experiment 1. FIG. 4A is a curve diagram showing a relationship between second region thickness and short-circuit current (J_{SC}) in Simulation Experiment 1. FIG. 4B is a curve diagram showing a relationship between second region thickness and fill factor (FF) in Simulation Experiment 1. FIG. 4C is a curve diagram showing a relationship between second region thickness and open-circuit voltage (V_{OC}) in Simulation Experiment 1.

It is clear from FIG. 4A to FIG. 4B that, as the thickness of the second region decreases, the short-circuit current increases. Although the reduction in thickness of the doped polysilicon layer has an influence on fill factor, it can be seen from FIG. 4D that the overall photoelectric conversion efficiency of the solar cell increases. Therefore, by using the thickness difference in the doped polysilicon layer, the short-circuit current and conversion efficiency of the battery can be effectively improved.

Simulation Experiment 2

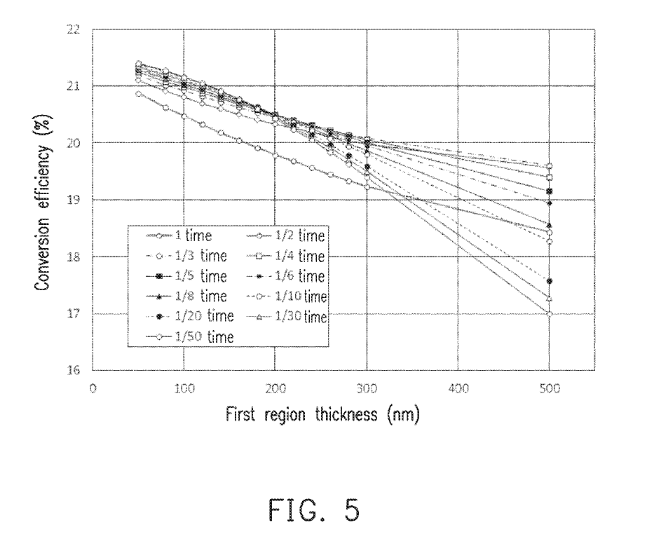

In addition, the solar cell of Simulation Experiment 1 was used as a simulating structure, and an analysis was conducted of variation in the thickness of the first region and in the ratio of the thickness of the second region to the thickness of the first region of the doped polysilicon layer in the solar cell. The results thereof were as shown in Table 1 below and FIG. 5.

TABLE 1

| | |
|---|---|
| First region | |
| thickness | Ratio of second region thickness to first region thickness |

| (nm) | 1 | 1/2 | 1/3 | 1/4 | 1/5 | 1/6 |
|---|---|---|---|---|---|---|
| 500 | 18.4313 | 19.5664 | 19.6046 | 19.3953 | 19.1594 | 18.9414 |
| 300 | 19.2362 | 19.982 | 20.0862 | 20.0628 | 20.0125 | 19.9607 |
| 280 | 19.3382 | 20.0428 | 20.1506 | 20.1369 | 20.1086 | 20.0634 |
| 260 | 19.4476 | 20.1114 | 20.2214 | 20.226 | 20.2053 | 20.179 |
| 240 | 19.562 | 20.1849 | 20.2959 | 20.3171 | 20.301 | 20.2904 |
| 220 | 19.6809 | 20.2624 | 20.3785 | 20.4085 | 20.4066 | 20.398 |
| 200 | 19.7915 | 20.3282 | 20.4492 | 20.4842 | 20.4984 | 20.4994 |
| 180 | 19.9168 | 20.4113 | 20.5357 | 20.5926 | 20.599 | 20.613 |
| 160 | 20.0471 | 20.4996 | 20.6254 | 20.6718 | 20.6982 | 20.7211 |
| 140 | 20.1829 | 20.5944 | 20.7193 | 20.7744 | 20.8057 | 20.8258 |
| 120 | 20.3248 | 20.696 | 20.8167 | 20.8781 | 20.917 | 20.9414 |
| 100 | 20.4734 | 20.8027 | 20.9179 | 20.9839 | 21.0252 | 21.0543 |
| 80 | 20.6237 | 20.9102 | 21.0166 | 21.0832 | 21.1253 | 21.1547 |
| 50 | 20.8755 | 21.1003 | 21.1919 | 21.2447 | 21.28 | 21.304 |

| First region | Ratio of second region thickness to first region thickness | | | | |
|---|---|---|---|---|---|
| thickness (nm) | 1/8 | 1/10 | 1/20 | 1/30 | 1/50 |
| 500 | 18.5725 | 18.2803 | 17.5733 | 17.2887 | 17.003 |
| 300 | 19.8696 | 19.7961 | 19.5956 | 19.5016 | 19.4054 |
| 280 | 19.9988 | 19.938 | 19.7843 | 19.7129 | 19.6362 |
| 260 | 20.1262 | 20.0882 | 19.9697 | 19.9106 | 19.844 |
| 240 | 20.2543 | 20.2283 | 20.1428 | 20.099 | 20.0519 |
| 220 | 20.3865 | 20.3696 | 20.3166 | 20.2835 | 20.242 |
| 200 | 20.4992 | 20.499 | 20.4737 | 20.4562 | 20.4334 |
| 180 | 20.6222 | 20.6249 | 20.6336 | 20.6233 | 20.6061 |
| 160 | 20.7458 | 20.7588 | 20.7723 | 20.7731 | 20.7667 |
| 140 | 20.8615 | 20.8822 | 20.9141 | 20.9166 | 20.911 |
| 120 | 20.9741 | 20.9946 | 21.0379 | 21.0468 | 21.0471 |
| 100 | 21.0914 | 21.113 | 21.1497 | 21.157 | 21.1606 |
| 80 | 21.1935 | 21.2152 | 21.2564 | 21.2664 | 21.2715 |
| 50 | 21.3333 | 21.35 | 21.3819 | 21.39 | 21.3942 |

*The unit of conversion efficiency is %.

It is clear from FIG. 5 that, as compared to the case where the first region and the second region have the same thickness, the thickness of the first region is preferably between 50 nm and 300 nm, and the thickness of the second region is preferably ½ time to 1/50 time the thickness of the first region. In other words, the thickness of the second region is preferably between 1 nm and 150 nm. Moreover, it is clear from Table 1 that, as the thickness of the first region decreases, the ratio of the thickness of the second region to the thickness of the first region preferably decreases. For example, if the thickness of the first region is 200 nm or less, the thickness of the second region is preferably 40 nm or less (i.e., the thickness of the second region is ⅕ time or less the thickness of the first region); if the thickness of the first region is 180 nm or less, the thickness of the second region is preferably 18 nm or less (i.e., the thickness of the second region is 1/10 time or less the thickness of the first region).

In summary, by setting a doped polysilicon layer to have different thickness ranges in different regions and using the doped polysilicon layer as a part of a passivation structure, collection of minority carriers and reduction in incident light absorption can both be achieved. Not only good thermostability, low resistivity and low light absorption can be obtained, but also the short-circuit current of the solar cell having the above structure can be improved, which thus achieves higher conversion efficiency.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A solar cell, comprising:
a silicon substrate having a first surface and a second surface;
a first passivation structure disposed on the first surface of the silicon substrate, the first passivation structure comprising:
a tunneling layer disposed on the first surface of the silicon substrate; and
a single doped polysilicon layer disposed on the tunneling layer, the single doped polysilicon layer comprising a first region and a second region having different thicknesses from each other, wherein the thickness of the first region is greater than the thickness of the second region, the thickness of the first region is between 50 nm and 300 nm, and the thickness of the second region is ½ time to 1/50 time the thickness of the first region; and
a first metal electrode disposed on the first region of the single doped polysilicon layer of the first passivation structure.

2. The solar cell of claim 1, wherein the tunneling layer comprises silicon oxide, silicon oxynitride, aluminum oxide or silicon nitride.

3. The solar cell of claim 1, wherein the single doped polysilicon layer comprises a polysilicon film, polycrystalline silicon oxide or polycrystalline silicon carbide.

4-5. (canceled)

6. The solar cell of claim 1, wherein an area of the first region is greater than or equal to an area of the first metal electrode.

7. The solar cell of claim 1, wherein an area of the first region is smaller than an area of the first metal electrode.

8. The solar cell of claim 1, further comprising a second passivation structure disposed on the second surface of the silicon substrate, the second passivation structure comprising:
a tunneling layer disposed on the second surface of the silicon substrate; and
a single doped polysilicon layer disposed on the tunneling layer, the single doped polysilicon layer comprising a first region and a second region having different thicknesses from each other, wherein the thickness of the first region is greater than the thickness of the second region, the thickness of the first region is between 50 nm and 500 nm, and the thickness of the second region is greater than 0 and equal to or less than 250 nm.

9. The solar cell of claim 8, further comprising a second metal electrode disposed on the first region of the single doped polysilicon layer of the second passivation structure.

10. The solar cell of claim 8, wherein the single doped polysilicon layer of the second passivation structure comprises a polysilicon film, polycrystalline silicon oxide or polycrystalline silicon carbide.

11. The solar cell of claim 8, wherein the tunneling layer of the second passivation structure comprises silicon oxide, silicon oxynitride, aluminum oxide or silicon nitride.

12. The solar cell of claim 8, wherein the thickness of the first region of the single doped polysilicon layer of the second passivation structure is between 50 nm and 300 nm, and the thickness of the second region of the single doped polysilicon layer of the second passivation structure is ½ time to 1/50 time the thickness of the first region of the single doped polysilicon layer of the second passivation structure.

13. The solar cell of claim 8, wherein the thickness of the second region of the single doped polysilicon layer of the second passivation structure is between 1 nm and 150 nm.

14. The solar cell of claim 9, wherein an area of the first region of the single doped polysilicon layer of the second passivation structure is greater than or equal to an area of the second metal electrode.

15. The solar cell of claim 9, wherein an area of the first region of the single doped polysilicon layer of the second passivation structure is smaller than an area of the second metal electrode.

16. The solar cell of claim 1, wherein sunlight enters the solar cell from the first surface or the second surface.
